(19) United States
(12) Patent Application Publication
(10) Pub. No.: US 2025/0336853 A1
(43) Pub. Date: Oct. 30, 2025

(54) HETEROGENEOUS HYBRID BONDING

(71) Applicant: International Business Machines Corporation, Armonk, NY (US)

(72) Inventors: Nikiforos Fokas, Albany, NY (US); Kevin Wayne Brew, Niskayuna, NY (US); Roy R. Yu, Poughkeepsie, NY (US)

(21) Appl. No.: 18/647,473

(22) Filed: Apr. 26, 2024

(51) Int. Cl. H01L 23/00

(52) U.S. Cl. CPC H01L 24/05; H01L 24/08; H01L 24/80; H01L 2224/05026; H01L 2224/05076; H01L 2224/05083; H01L 2224/05147; H01L 2224/08145; H01L 2224/80895; H01L 2224/80896

(57) ABSTRACT

A semiconductor device includes an electrically conductive contact embedded in a region of dielectric material. The electrically conductive contact has an uppermost surface that includes a recess and a depression. The recess is recessed a first depth relative to an uppermost surface of the region of dielectric material, and the depression recessed a second depth relative to the uppermost surface of the region of dielectric material. The second depth greater than the first depth. The semiconductor device further includes a region of fill material formed in the recess and the depression of the uppermost surface of the electrically conductive contact. The fill material includes an intermetallic alloy. The intermetallic alloy may be an alloy of copper and one or more of gold, palladium, cobalt, tin, or nickel.

### BACKGROUND

The present disclosure relates to the semiconductor device fields. In particular, the present disclosure relates to semiconductor devices that utilize hybrid bonding.

Hybrid bonding is a permanent bond that combines a dielectric bond (between two dielectric materials) with a metal bond (between two metal materials) to form interconnections. Accordingly, hybrid bonding can be used to connect dies in packages using small metal-to-metal connections, enabling face-to-face connection of the wafers.

### SUMMARY

Embodiments of the present disclosure include a semiconductor device. The semiconductor device includes an electrically conductive contact embedded in a region of dielectric material. The electrically conductive contact has an uppermost surface including a recess and a depression. The recess is recessed a first depth relative to an uppermost surface of the region of dielectric material, and the depression is recessed a second depth relative to the uppermost surface of the region of dielectric material. The second depth greater than the first depth. The semiconductor device further includes a region of fill material formed in the recess and the depression of the uppermost surface of the electrically conductive contact. The fill material includes an intermetallic alloy.

Additional embodiments of the present disclosure include a semiconductor device. The semiconductor device includes a first electrically conductive contact embedded in a first region of dielectric material. The first electrically conductive contact has an uppermost surface including a recess and a depression. The recess is recessed a first depth relative to an uppermost surface of the first region of dielectric material, and the depression is recessed a second depth relative to the uppermost surface of the first region of dielectric material. The second depth is greater than the first depth. The semiconductor device further includes a second electrically conductive contact embedded in a second region of dielectric material. The second electrically conductive contact has a lowermost surface that is recessed relative to a lowermost surface of the second region of dielectric material. The semiconductor device further includes a first region of fill material formed in the recess and the depression of the uppermost surface of the first electrically conductive contact. The semiconductor device further includes a second region of the fill material arranged on the lowermost surface of the second electrically conductive contact. The fill material includes an intermetallic alloy, and the first region of the fill material is in direct contact with the second region of the fill material.

Additional embodiments of the present disclosure include a method of forming a semiconductor device. The method includes providing a first electrically conductive contact embedded in a first region of dielectric material. The first electrically conductive contact has an uppermost surface including a recess and a depression. The recess is recessed a first depth relative to an uppermost surface of the region of dielectric material, and the depression is recessed a second depth relative to the uppermost surface of the region of dielectric material, the second depth greater than the first depth. The method further includes forming a first region of fill material in the recess and the depression of the uppermost surface of the first electrically conductive contact. The fill material includes an intermetallic alloy.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

FIG. 1 illustrates a cross-sectional schematic view of a semiconductor device configured for hybrid bonding, in accordance with embodiments of the present disclosure.

FIG. 2 illustrates a cross-sectional schematic view of a semiconductor device formed with hybrid bonding, in accordance with embodiments of the present disclosure.

FIG. 3 illustrates a cross-sectional schematic view of a semiconductor device formed with hybrid bonding, in accordance with embodiments of the present disclosure.

FIG. 4 illustrates a flowchart of a method for forming a semiconductor device, in accordance with embodiments of the present disclosure.

### DETAILED DESCRIPTION

According to an aspect of the present disclosure, there is provided a semiconductor device. The semiconductor device includes an electrically conductive contact embedded in a region of dielectric material. The electrically conductive contact has an uppermost surface including a recess and a depression. The recess is recessed a first depth relative to an uppermost surface of the region of dielectric material, and the depression is recessed a second depth relative to the uppermost surface of the region of dielectric material. The second depth is greater than the first depth. The semiconductor device further includes a region of fill material formed in the recess and the depression of the uppermost surface of the electrically conductive contact. The fill material includes an intermetallic alloy. By utilizing an intermetallic alloy on the uppermost surface of the electrically conductive contact, the semiconductor device can be configured for hybrid bonding that benefits from having an additional conductive material besides copper at the surface of the contact without the drawbacks of using the additional conductive material for the entire contact.

In embodiments, the intermetallic alloy includes copper. Depending on the metal that is alloyed with copper, such embodiments may enable, for example, forming a bond with a lower bonding temperature than copper while maintaining a resulting electrical resistivity that is close to that of copper and/or improving properties such as reducing electromigration and/or selective growth on the copper surface of the electrically conductive contact and/or lower surface oxidation at the bonding interface.

In embodiments, an uppermost surface of the region of the fill material is substantially coplanar with the uppermost surface of the region of dielectric material. Such embodiments facilitate robust hybrid bonding by enabling the bond with the dielectric material at the same surface height as the bond with the contact material.

In embodiments, the semiconductor device further includes a barrier layer arranged between the uppermost surface of the electrically conductive contact and the fill material such that the barrier layer is in direct contact with the uppermost surface of the electrically conductive contact. Such embodiments facilitate containment of the fill material on top of the electrically conductive contact.

In embodiments, the semiconductor device further includes a cap formed on the uppermost surface of the region of dielectric material. Such embodiments reduce migration of the material of the electrically conductive contact.

In embodiments, an uppermost surface of the region of the fill material is substantially coplanar with an uppermost surface of the cap. Such embodiments facilitate robust hybrid bonding by enabling the bond with the cap on top of the dielectric material at the same surface height as the bond with the fill material on top of the contact material.

In embodiments, the semiconductor device further includes a liner separating the electrically conductive contact and the region of dielectric material. Such embodiments reduce migration of the material of the electrically conductive contact.

In embodiments, an uppermost surface of the liner is substantially coplanar with an uppermost surface of the region of the fill material. Such embodiments facilitate robust hybrid bonding by eliminating a height differential at the bonding surfaces of the dielectric material and the contact material.

According to an aspect of the present disclosure, there is provided a semiconductor device. The semiconductor device includes a first electrically conductive contact embedded in a first region of dielectric material. The first electrically conductive contact has an uppermost surface including a recess and a depression. The recess is recessed a first depth relative to an uppermost surface of the first region of dielectric material, and the depression is recessed a second depth relative to the uppermost surface of the first region of dielectric material. The second depth greater than the first depth. The semiconductor device further includes a second electrically conductive contact embedded in a second region of dielectric material. The second electrically conductive contact has a lowermost surface that is recessed relative to a lowermost surface of the second region of dielectric material. The semiconductor device further includes a first region of fill material formed in the recess and the depression of the uppermost surface of the first electrically conductive contact and a second region of the fill material arranged on the lowermost surface of the second electrically conductive contact. The fill material includes an intermetallic alloy, and the first region of the fill material is in direct contact with the second region of the fill material. By providing a fill material including an intermetallic alloy on the uppermost surfaces of the electrically conductive contacts, the semiconductor device enables hybrid bonding that benefits from having the additional conductive metal that is alloyed with copper in the intermetallic alloy at the surface of the contacts without the drawbacks of using the additional conductive metal for the entire contacts.

In embodiments, an uppermost surface of the first region of the fill material is substantially coplanar with the uppermost surface of the first region of dielectric material. Such embodiments facilitate robust hybrid bonding by enabling the bond with the dielectric material at the same surface height as the bond with the contact material.

In embodiments, the semiconductor device further includes a barrier layer arranged between the uppermost surface of the first electrically conductive contact and the first region of the fill material such that the barrier layer is in direct contact with the uppermost surface of the first electrically conductive contact. Such embodiments facilitate containment of the fill material on top of the electrically conductive contact.

In embodiments, the semiconductor device further includes a cap formed on the uppermost surface of the first region of dielectric material. Such embodiments reduce migration of the material of the electrically conductive contact.

In embodiments, an uppermost surface of the first region of the fill material is substantially coplanar with an uppermost surface of the cap. Such embodiments facilitate robust hybrid bonding by enabling the bond with the cap on top of the dielectric material at the same surface height as the bond with the fill material on top of the contact material.

In embodiments, the semiconductor device further includes a liner separating the first electrically conductive contact and the first region of dielectric material. Such embodiments reduce migration of the material of the electrically conductive contact.

In embodiments, an uppermost surface of the liner is substantially coplanar with an uppermost surface of the first region of the fill material. Such embodiments facilitate robust hybrid bonding by eliminating a height differential at the bonding surfaces of the dielectric material and the contact material.

According to an aspect of the present disclosure, there is provided a method of forming a semiconductor device. The method includes providing a first electrically conductive contact embedded in a first region of dielectric material. The first electrically conductive contact has an uppermost surface including a recess and a depression. The recess is recessed a first depth relative to an uppermost surface of the region of dielectric material, and the depression is recessed a second depth relative to the uppermost surface of the region of dielectric material. The second depth is greater than the first depth. The method further includes forming a first region of fill material in the recess and the depression of the uppermost surface of the first electrically conductive contact. The fill material includes an intermetallic alloy. By providing a fill material including the intermetallic alloy on the uppermost surfaces of the electrically conductive contact, the semiconductor device enables hybrid bonding that benefits from having an additional conductive metal that is alloyed with copper at the surface of the contact without the drawbacks of using the additional conductive metal for the entire contact.

In embodiments, the method further includes providing a second electrically conductive contact embedded in a second region of dielectric material. The second electrically conductive contact has a lowermost surface that is recessed relative to a lowermost surface of the second region of dielectric material. In such embodiments, the method further includes forming a second region of the fill material on the lowermost surface of the second electrically conductive contact and bonding the first region of the fill material directly to the second region of the fill material. By providing a fill material including the intermetallic alloy on the uppermost surfaces of both electrically conductive contacts, the semiconductor device enables hybrid bonding that benefits from having the intermetallic alloy at the surfaces of the contacts without the drawbacks of using the metal alloyed with copper in the intermetallic alloy for the entire contacts.

In embodiments, bonding the first region of dielectric material to the second region of dielectric material. Such embodiments enable hybrid bonding by enabling bonding between the dielectric materials as well as bonding between the electrical contact materials.

In embodiments, bonding the first region of dielectric material to the second region of dielectric material includes forming a cap on at least one of the uppermost surface of the first region of dielectric material and the lowermost surface of the second region of dielectric material. Such embodiments reduce migration of the material of the electrically conductive contact.

In embodiments, bonding the first region of the fill material directly to the second region of the fill material includes cold bonding. Such embodiments enable hybrid bonding with reduced likelihood of damaging other functional components of the semiconductor device by reducing or eliminating the need to apply heat to bond the contacts.

Aspects of the present disclosure relate generally to the semiconductor fields. In particular, the present disclosure relates to hybrid bonding in semiconductor manufacturing. While the present disclosure is not necessarily limited to such applications, various aspects of the disclosure may be appreciated through a discussion of various examples using this context.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

In general, the various processes used to form a micro-chip that will be packaged into an IC fall into four general categories, namely, film deposition, removal/etching, semiconductor doping and patterning/lithography.

Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching is any process that removes material from the wafer. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material. Gas-cluster ion beam (GCIB), also referred to as neutral particle beam (NPB) may be used as a dry removal process.

Semiconductor doping is the modification of electrical properties by doping, for example, transistor sources and drains, generally by diffusion and/or by ion implantation. These doping processes are followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and gradually the conductors, insulators and selectively doped regions are built up to form the final device.

Turning now to an overview of technologies that are more specifically relevant to aspects of the present disclosure, in general, hybrid bonding is an important bonding technique in advanced semiconductor packaging. As semiconductor technology continues to scale to smaller and smaller components, three-dimensional packaging must also evolve to accommodate and enable those components. One existing three-dimensional packaging strategy includes using microbumps to provide vertical interconnects between chips by using small copper bumps on dies. Such bumps can range in size, and have been scaled down to enable 20 μm or 10 μm pitches. However, scaling below 10 μm pitches introduces accuracy and reliability challenges, which impact the integrity and reliability of the resulting device. Hybrid bonding can enable bonding below 10 μm pitches by avoiding the use of microbumps. Instead, hybrid bonding utilizes metal contacts (for example, copper wires) embedded in surrounding dielectric (typically SiO2 or SiCN) to connect dies in packages using small metal-to-metal (typically, copper-to-copper) connections in combination with dielectric-to-dielectric connections. Hybrid bonding can thus enable superior interconnect density, thereby enabling higher bandwidth while improving power and signal integrity.

One challenge that arises with the use of hybrid bonding is that the chiplets that are being bonded together may include memory devices. Some memory devices, in particular phase-change memory devices, may be negatively impacted by the heat applied during hybrid bonding. For example, temperature sensitive inference chips, such as those employing phase-change memory, that have been programmed prior to bonding could be erased or de-programmed by the heat that is applied during the bonding process.

Another challenge that arises in hybrid bonding is that the copper, which is almost ubiquitously used for the metal bonding contact, tends to suffer from void formation during hybrid bonding processing and can require removal of intrinsic oxides formed on its surface that can prevent bonding. In particular, hybrid bonding processes typically include recessing the copper contact, for example using CMP, at the bonding interface surface prior to bonding. This process commonly results in galvanic corrosion of the copper, causing the formation of voids at the corners of the copper contact, which can negatively impact the reliability of the chip. Such voids may migrate through the metal, increasing the negative effect. The negative impact on chip reliability is exacerbated as the pitch decreases.

One approach to address the copper voids has been the attempt to use metal nitrides to form conduction barriers or simple alloys to improve hybrid bonding. However, the use of such materials in this manner is undesirable because it results in an increase in the resistance between bonded chiplets. Such an increase causes higher power consumption, which makes the result impractical when scaled up to the entire device.

Embodiments of the present disclosure may enable reliable methods and structures for hybrid bonding while avoiding problematic void formation and increased resistance between bonded chiplets by utilizing a fill material on the bonding surface of the metal contact, wherein the fill material includes an intermetallic alloy. As used herein, the term “intermetallic alloy” refers to a homogeneous material including at least two metals, one of which is copper. The other of the at least two metals can be gold, palladium, tin, cobalt, zinc, nickel, or another metal that, when alloyed with copper in a specific stoichiometry, results in advantageous material properties, such as increased atmospheric inertness, reduced electrical resistivity, and/or the prevention of surface oxide formation.

Notably, simply using another metal, such as gold, instead of copper as the metal contact may not be a practical solution due to its prohibitive cost. Additionally, by using a fill material that includes an intermetallic alloy, it is possible to use a fill material having a stoichiometrically stable superstructure with lower resistivity that is close to that of pure copper while also having a bonding temperature that may be lower than that necessary for pure copper.

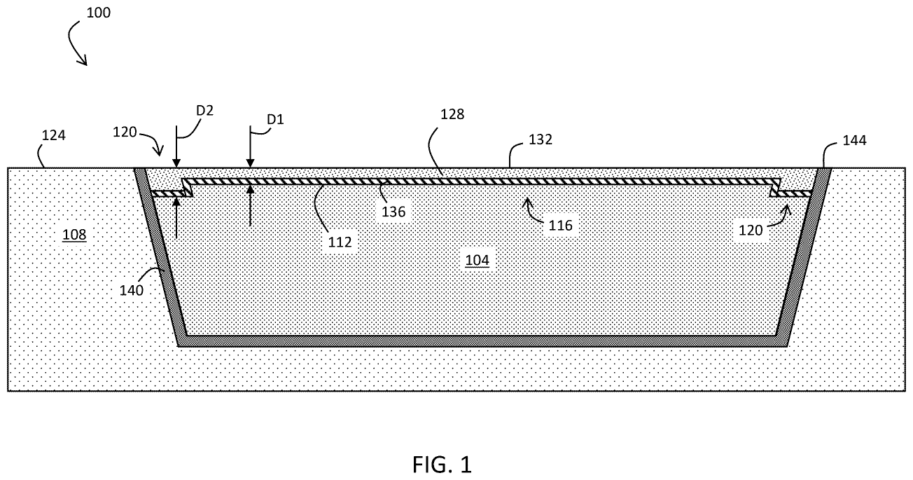

FIG. 1 depicts an example semiconductor device 100 that is configured for hybrid bonding and includes an electrically conductive contact 104 embedded in a region of dielectric material 108. In accordance with embodiments of the present disclosure, the electrically conductive contact 104 can be made of a conductive metal, such as, for example copper. In accordance with embodiments of the present disclosure, the region of dielectric material 108 can be made of, for example, SiO2, SiCOH, SiN, or SiCN.

As shown, the electrically conductive contact 104 has an uppermost surface 112 that includes a recess 116 and depressions 120. The recess 116 is recessed a first depth D1 relative to an uppermost surface 124 of the region of dielectric material 108. The depressions 120 are recessed a second depth D2 relative to the uppermost surface 124 of the region of dielectric material 108. In other words, the uppermost surface 112 of the electrically conductive contact 104 is not a planar surface due to the presence of the recess 116 and the depressions 120. As shown, in accordance with embodiments of the present disclosure, the second depth D2 of the depressions 120 is greater than the first depth D1 of the recess 116.

In accordance with embodiments of the present disclosure, the recess 116 can be formed, for example, by CMP or another planarizing process that is performed on the uppermost surface 112 of the electrically conductive contact 104 as part of the hybrid bonding process. In other words, the recess 116 may be formed intentionally. In contrast, in accordance with embodiments of the present disclosure, the depressions 120, which are formed at the corners of the electrically conductive contact 104, can be formed, for example, by galvanic corrosion of the copper that results from the performance of the CMP or other planarization process that is performed on the uppermost surface 112 of the electrically conductive contact 104. In other words, the depressions 120 may be formed unintentionally.

Notably, in alternative embodiments of the present disclosure, the second depth D2 of the depressions 120 may not be greater than the first depth D1 of the recess 116.

As shown in FIG. 1, the device 100 further includes a region of fill material 128 formed in the recess 116 and the depressions 120 on the uppermost surface 112 of the electrically conductive contact 104. More specifically, the region of fill material 128 fills the recess 116 and the depressions 120 such that an uppermost surface 132 of the region of fill material 128 is substantially coplanar with the uppermost surface 124 of the region of dielectric material 108.

As used herein, the term “coplanar” refers to two surfaces that lie in a common plane. In other words, two surfaces are coplanar if there exists a geometric plane that contains all the points of both of the surfaces. As used herein, the term “substantially” refers to the inclusion of deviations that do not affect the intended outcome of the term that it modifies. For example, surfaces that are substantially parallel include surfaces that are not exactly parallel but which do not deviate from being exactly parallel to an extent that affects the intended outcome of the parallel nature of the surfaces. Accordingly, two surfaces may be referred to as being substantially coplanar despite deviations from coplanarity, so long as those deviations do not impact the desired result of the coplanarity. In this instance, the desired result of the coplanarity of the uppermost surface 132 of the region of fill material 128 and the uppermost surface 124 of the region of dielectric material 108 is to facilitate the formation of a hybrid bond between the device 100 and another device by ensuring that contact is made evenly across the region of fill material 128 and the region of dielectric material 108.

In some embodiments of the present disclosure, the fill material includes gold. In accordance with some embodiments of the present disclosure, the fill material can be pure gold. In accordance with other embodiments of the present disclosure, the fill material can be an intermetallic alloy including gold and copper. In such embodiments, the fill material is one that has a lower bonding temperature than pure copper and/or has an electrical resistivity that is close to that of pure copper.

In accordance with embodiments of the present disclosure, the fill material is an intermetallic alloy including gold or palladium in a specific stoichiometry with the copper such that the intermetallic alloy has advantageous material properties of increased atmospheric inertness and reduced electrical resistivity. For example, the fill material can include an atomic percentage of gold of 25%. In accordance with embodiments of the present disclosure, the fill material can include an atomic percentage of gold of 50%. Notably, alloys that are 25% gold and 75% copper by atomic percentage and alloys that are 50% gold and 50% copper by atomic percentage have an electrical resistivity that is much closer to that of pure copper and/or pure gold than other alloys of gold and copper. Similarly, palladium and copper have been shown at compositions near 50% palladium and 50% copper to exhibit lower resistivity, near that of pure copper. Such alloys may be referred to as “superalloys.” In accordance with other embodiments of the present disclosure, the fill material can include other atomic percentages of gold and copper or palladium and copper that enable a lower bonding temperature than pure copper and/or that have an electrical resistivity that is relatively close to that of pure copper.

In accordance with some embodiments of the present disclosure, the fill material can include zinc or tin in a specific stoichiometry with the copper such that the intermetallic alloy reduces the likelihood that subsequent reactions with the fill material will form voids within the fill material.

By using a fill material including an intermetallic alloy that has a lower bonding temperature than the copper of the electrically conductive contact 104 and that has an electrical resistivity that is close to that of the copper of the electrically conductive contact 104, the fill material improves the suitability of the device 100 for hybrid bonding because it reduces the temperature required for the hybrid bonding process. For example, the bonding temperature for copper is around 380-450° C., and gold can be bonded at temperatures as low as 260° C., depending on applied pressure during bonding. In fact, at higher pressures, gold can cold-weld itself due to its inertness, which resists forming an oxidation layer, making it compatible with thermally sensitive components. Accordingly, the lower bonding temperature of gold is much better suited for instances where thermally sensitive chiplets are being hybrid bonded.

The use of gold or a gold-copper alloy for the fill material also has high versatility because it enables the formation of the region of fill material using a variety of methods, like selective growth of the fill material on a selectively recessed surface, selective growth of self-assembled monolayers of the fill material, deposition of the fill material with anneal cycling, and electroless deposition or electroless plating of the fill material.

The presence of the region of intermetallic alloy fill material on the copper electrically conductive contact can also reduce oxidation of the copper of the electrically conductive contact as copper surfaces can be susceptible to moisture reactions during bonding processes. Thus, the intermetallic alloy fill material can enable a superior bonding surface relative to copper.

Additionally, the fill material improves the integrity and reliability of the device 100 because it fills the depressions 120 formed at the corners of the electrically conductive contact 104 by galvanic corrosion during CMP and resists further galvanic corrosion on possible subsequent CMP for planarization of the conductive contact fill. For example, gold also has a high propensity for void-free bonding. Additionally, the fill material enables these benefits without compromising the low electrical resistivity of the device 100.

In the embodiment shown in FIG. 1, the device 100 further includes a barrier layer 136 arranged between the uppermost surface 112 of the electrically conductive contact 104 and the region of fill material 128 such that the barrier layer 136 is in direct contact with the uppermost surface of the electrically conductive contact 104. As shown, the barrier layer 136 extends across the entirety of the uppermost surface 112 of the electrically conductive contact 104. In such embodiments, the barrier layer 136 is configured to contain the fill material within the region of fill material 128. In other words, the barrier layer 136 is configured to prevent the fill material from migrating into or mixing with the material of the electrically conductive contact 104. In accordance with embodiments of the present disclosure, the barrier layer 136 can be formed of, for example, Ni. In other embodiments, the barrier layer 136 can be formed of another material that will contain the fill material within the region of fill material 128.

As shown, in such embodiments, the barrier layer 136 fills some of the recess 116 and the depressions 120 formed in the uppermost surface 112 of the electrically conductive contact 104. In such embodiments, the region of fill material 128 is formed on top of the barrier layer 136. Accordingly, in such embodiments, the area formed by the recess 116 and depressions 120 that is not filled with the barrier layer 136 is filled with the fill material. In other words, the depths D1 and D2 are partially filled with the barrier layer 136 and are partially filled with the region of fill material 128.

In alternative embodiments of the present disclosure, the device 100 may be formed without a barrier layer. In such embodiments, the region of fill material 128 is formed directly on the uppermost surface 112 of the electrically conductive contact 104 and fills all of the area formed by the recess 116 and the depressions 120.

Notably, embodiments of the present disclosure enable hybrid bonding without the need for a glue layer on the region of dielectric material by utilizing a recessed uppermost surface of the electrically conductive contact and filling that recess with a second electrically conductive material. The second electrically conductive material can be, for example, an alloy that enables the prevention of detrimental Kirkendall voids formed from systems such as an alloy of tin and copper, gold and copper, cobalt and copper, or palladium and copper. Avoiding the need for such a glue layer is desirable because the use of a glue layer imparts higher thermal resistance between the bonded chips.

In the embodiment shown in FIG. 1, the device 100 further includes a liner 140 separating the electrically conductive contact 104 and the region of dielectric material 108. In such embodiments, the liner 140 is in direct contact with the electrically conductive contact 104 and is in direct contact with the region of dielectric material 108. As shown, the liner 140 further separates the region of fill material 128 and the barrier layer 136 from the region of dielectric material 108. In such embodiments, the liner 140 is configured to prevent the materials of the electrically conductive contact 104, the region of fill material 128, and/or the barrier layer 136 from migrating into or mixing with the dielectric material of the region of dielectric material 108. In accordance with embodiments of the present disclosure, the liner 140 can be formed of, for example, TiN. In other embodiments, the liner 140 can be formed of another material that will prevent the materials of the electrically conductive contact 104, the region of fill material 128, and/or the barrier layer 136 from migrating into or mixing with the dielectric material of the region of dielectric material 108.

As shown, an uppermost surface 144 of the liner 140 is substantially coplanar with the uppermost surface 132 of the region of fill material 128. The desired result of the coplanarity of the uppermost surface 144 of the liner 140 and the uppermost surface 132 of the region of fill material 128 is to facilitate the formation of a hybrid bond between the device 100 and another device by ensuring that contact is made evenly across the region of fill material 128 and the region of dielectric material 108 without any interference due to a discrepancy in the surface caused by the liner 140.

In alternative embodiments of the present disclosure, the barrier layer 136 can be formed using processes that result in the barrier layer 136 being formed on the inward facing surfaces of the liner 140 as well as on the uppermost surface 112 of the electrically conductive contact 104.

In alternative embodiments of the present disclosure, the device 100 may be formed without a liner or may be formed with a liner that does not fully separate the electrically conductive contact 104, the region of fill material 128, and/or the barrier layer 136 from the region of dielectric material 108. In such embodiments, at least some portions of at least some of the electrically conductive contact 104, the region of fill material 128, and/or the barrier layer 136 may be formed in direct contact with the region of dielectric material 108.

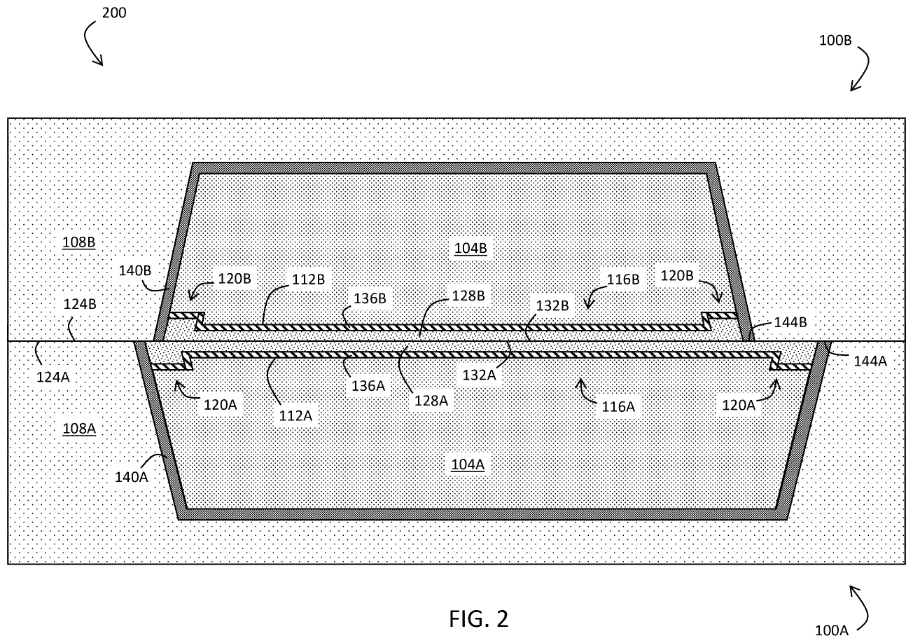

FIG. 2 illustrates a cross-sectional schematic view of a semiconductor device 200 formed with hybrid bonding, in accordance with embodiments of the present disclosure. The semiconductor device 200 shown in FIG. 2 includes a first semiconductor device 100A and a second semiconductor device 100B, each of which is substantially similar to the device 100 described above with respect to FIG. 1. More specifically, the first semiconductor device 100A and the second semiconductor device 100B are bonded together using hybrid bonding to form the semiconductor device 200. Notably, in alternative embodiments, a semiconductor device similar to that of semiconductor device 200 can be formed using only one semiconductor device that is substantially similar to the device 100 described above with respect to FIG. 1 bonded together with one conventional semiconductor device.

Accordingly, the semiconductor device 200 includes a first electrically conductive contact 104A embedded in a first region of dielectric material 108A. The first electrically conductive contact 104A has an uppermost surface 112A that includes a recess 116A and depressions 120A. The recess 116A and the depressions 120A are recessed relative to an uppermost surface 124A of the first region of dielectric material 108A in the same manner as described above with respect to the device 100. The semiconductor device 200 further includes a second electrically conductive contact 104B embedded in a second region of dielectric material 108B such that the second semiconductor device 100B is substantially similar to the first semiconductor device 100A.

As shown, in accordance with some embodiments of the present disclosure, the first semiconductor device 100A and the second semiconductor device 100B can have different dimensions. However, the differences in their dimensions can be a function of their role in the semiconductor device 200. For example, the first semiconductor device 100A may be part of a logic die and the second semiconductor device 100B may be part of a memory die such that the electrically conductive contacts for the first semiconductor device 100A are of different dimensions than the electrically conductive contacts for the second semiconductor device 100B. Such differences are not significant enough to impact the ability to bond the first semiconductor device 100A and the second semiconductor device 100B together with hybrid bonding as disclosed herein. In other embodiments, the first semiconductor device 100A and the second semiconductor device 100B can have substantially the same dimensions.

The semiconductor device 200 further includes a first region of fill material 128A formed in the recess 116A and depressions 120A of the uppermost surface 112A of the first electrically conductive contact 104A. Analogously, the semiconductor device 200 also includes a second region of fill material 128B formed in the recess 116B and depressions 120B of the lowermost surface 112B of the second electrically conductive contact 104B. As shown in FIG. 2, because the first semiconductor device 100A is bonded to the second semiconductor device 100B to form the semiconductor device 200, the first region of fill material 128A is in direct contact with the second region of fill material 128B. In the same manner as described above with respect to the semiconductor device 100, the fill material of the first and second semiconductor devices 100A and 100B includes an intermetallic alloy.

In the same manner as described above with respect to the semiconductor device 100, the uppermost surface 132A of the first region of fill material 128A is substantially coplanar with the uppermost surface 124A of the first region of dielectric material 108A. Analogously, the lowermost surface 132B of the second region of fill material 128B is substantially coplanar with the lowermost surface 124B of the second region of dielectric material 108B.

In the same manner as described above with respect to the semiconductor device 100, the first semiconductor device 100A includes a barrier layer 136A arranged between the uppermost surface 112A of the first electrically conductive contact 104A and the first region of fill material 128A such that the barrier layer 136A is in direct contact with the uppermost surface 112A of the first electrically conductive contact 104A. Analogously, in accordance with embodiments of the present disclosure, the second semiconductor device 100B includes a barrier layer 136B arranged between the lowermost surface 112B of the second electrically conductive contact 104B and the second region of fill material 128B such that the barrier layer 136B is in direct contact with the lowermost surface 112B of the second electrically conductive contact 104B.

In the same manner as described above with respect to the semiconductor device 100, the first semiconductor device 100A includes a liner 140A separating the first electrically conductive contact 104A and the first region of dielectric material 108A. An uppermost surface 144A of the liner 140A is substantially coplanar with the uppermost surface 132A of the first region of fill material 128A. Analogously, in accordance with embodiments of the present disclosure, the second semiconductor device 100B includes a liner 140B separating the second electrically conductive contact 104B and the second region of dielectric material 108B. A lowermost surface 144B of the liner 140B is substantially coplanar with the lowermost surface 132B of the second region of fill material 128B.

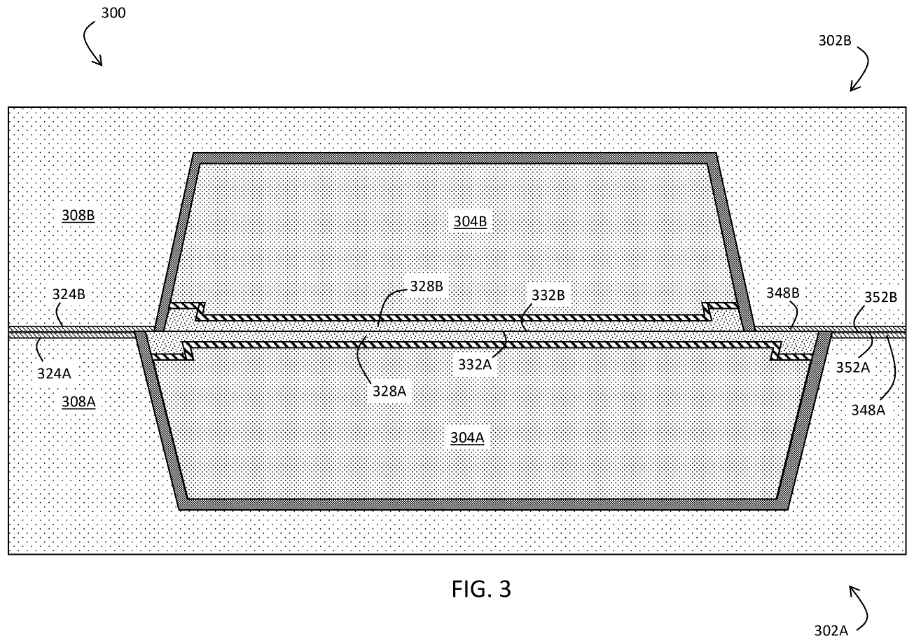

FIG. 3 illustrates a cross-sectional schematic view of a semiconductor device 300 formed with hybrid bonding, in accordance with embodiments of the present disclosure. In the embodiment shown, the semiconductor device 300 includes a first semiconductor device 302A that is substantially similar to the first semiconductor device 100A and a second semiconductor device 302B that is substantially similar to the second semiconductor device 100B described above with reference to FIG. 2. The first and second semiconductor devices 302A and 302B differ from the first and second semiconductor devices 100A and 100B, however, in that each of the first and second semiconductor devices 302A and 302B includes a respective cap 348A, 348B. More specifically, the first semiconductor device 302A includes a cap 348A formed on the uppermost surface 324A of the first region of dielectric material 308A. Analogously, the second semiconductor device 302B includes a cap 348B formed on the lowermost surface 324B of the second region of dielectric material 308B.

As shown, the cap 348A is formed such that an uppermost surface 352A of the cap 348A is substantially coplanar with the uppermost surface 332A of the first region of fill material 328A. The desired result of the coplanarity of the uppermost surface 352A of the cap 348A and the uppermost surface 332A of the first region of fill material 328A is to facilitate the formation of a hybrid bond between the first semiconductor device 302A and the second semiconductor device 302B by ensuring that contact is made evenly across the region of fill material 328A and the cap 348A. Accordingly, in such embodiments, the uppermost surface 332A of the first region of fill material 328A is not substantially coplanar with the uppermost surface 324A of the first region of dielectric material 308A.

Analogously, the cap 348B is formed such that a lowermost surface 352B of the cap 348B is substantially coplanar with the lowermost surface 332B of the second region of fill material 328B. The desired result of the coplanarity of the lowermost surface 352B of the cap 348B and the lowermost surface 332B of the second region of fill material 328B is to facilitate the formation of a hybrid bond between the first semiconductor device 302A and the second semiconductor device 302B by ensuring that contact is made evenly across the second region of fill material 328B and the cap 348B. Accordingly, in such embodiments, the lowermost surface 332B of the second region of fill material 328B is not substantially coplanar with the lowermost surface 324B of the second region of dielectric material 308B.

In accordance with at least one embodiment of the present disclosure, the caps 348A and 348B can be formed of SiCN. In such embodiments, the dielectric material of the regions of dielectric material 308A and 308B can be formed of SiO2. In such embodiments, the SiCN enables the dielectric-to-dielectric bond of the hybrid bonding between the first and second semiconductor devices 302A and 302B and prevents the migration of copper from the first and second electrically conductive contacts 304A and 304B into the first and second regions of dielectric material 308A and 308B, respectively. In alternative embodiments, the caps 348A and 348B can be made of a different material that enables the dielectric-to-dielectric bond of the hybrid bonding between the first and second semiconductor devices 302A and 302B and prevents the migration of copper from the first and second electrically conductive contacts 304 and 304B into the first and second regions of dielectric material 308A and 308B, respectively. In alternative embodiments, the caps 348A and 348B can be made of different materials than one another.

In accordance with at least one alternative embodiment of the present disclosure, only one of the first and second semiconductor devices 302A and 302B can include a cap instead of each of the first and second semiconductor devices 302A and 302B including a cap. In such embodiments, the dielectric-to-dielectric bond of the hybrid bond can include bonding the cap of one of the semiconductor devices to the region of dielectric material of the other of the semiconductor devices. In such embodiments, this bond may prevent the migration of copper from the first and second electrically conductive contacts 304 and 304B into the first and second regions of dielectric material 308A and 308B.

In accordance with embodiments of the present disclosure, the semiconductor device 100 shown in FIG. 1 could include a cap substantially similar to the cap 348A described above with reference to the semiconductor device 300 shown in FIG. 3.

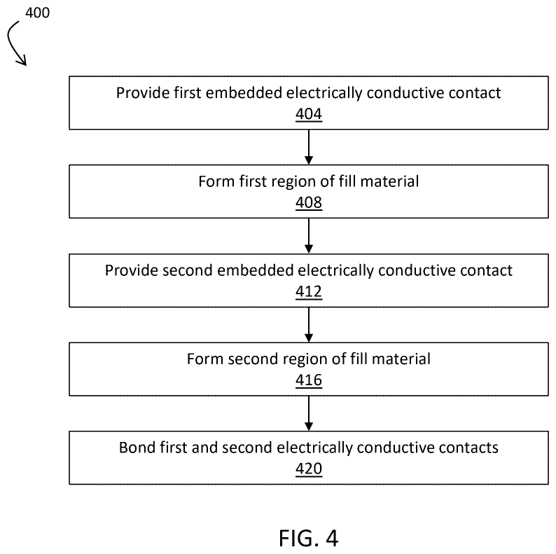

FIG. 4 illustrates a flowchart of a method 400 for forming a semiconductor device, in accordance with embodiments of the present disclosure. The method 400, or portion(s) thereof, can be performed to form a semiconductor device such as one of semiconductor devices 100, 100A, 100B, 200, 302A, 302B, or 300, described above with reference to FIGS. 1-3.

The method 400 includes operation 404, wherein a first electrically conductive contact (for example, an electrically conductive contact substantially similar to the electrically conductive contact 104A described above with reference to FIG. 2) embedded in a first region of dielectric material (for example, a region of dielectric material substantially similar to the region of dielectric material 108A described above with reference to FIG. 2) is provided. The first electrically conductive contact has an uppermost surface including a recess and a depression. The recess is recessed a first depth relative to an uppermost surface of the first region of dielectric material and the depression is recessed a second depth relative to the uppermost surface of the first region of dielectric material. The second depth is greater than the first depth.

The method 400 further includes operation 408, wherein a first region of fill material (for example, a region of fill material substantially similar to the region of fill material 128A described above with reference to FIG. 2) is formed in the recess and the depression of the uppermost surface of the first electrically conductive contact. The fill material includes an intermetallic alloy.

In accordance with embodiments of the present disclosure, the method 400 further includes operation 412, wherein a second electrically conductive contact (for example, an electrically conductive contact substantially similar to the electrically conductive contact 104B described above with reference to FIG. 2) embedded in a second region of dielectric material (for example, a region of dielectric material substantially similar to the region of dielectric material 108B described above with reference to FIG. 2) is provided. The second electrically conductive contact has a lowermost surface that is recessed relative to a lowermost surface of the second region of dielectric material.

In accordance with embodiments of the present disclosure, the method 400 further includes operation 416, wherein a second region of fill material (for example, a region of fill material substantially similar to the region of fill material 128B described above with reference to FIG. 2) is formed on the lowermost surface of the second electrically conductive contact.

In accordance with embodiments of the present disclosure, the method further includes operation 420, wherein the first region of fill material is bonded directly to the second region of fill material. In accordance with embodiments of the present disclosure, the performance of operation 420 further includes bonding the first region of dielectric material to the second region of dielectric material. Thus, in accordance with embodiments of the present disclosure, operation 420 includes hybrid bonding the first electrically conductive contact embedded in the first region of dielectric material with the second electrically conductive contact embedded in the second region of dielectric material.

In accordance with at least one embodiment of the present disclosure, the performance of each of operations 404-420 can include the performance of a number of sub-operations.

In accordance with at least one embodiment of the present disclosure, the performance of operation 404 can include forming the first electrically conductive contact embedded in the first region of dielectric material using lithography to create an opening in the first region of dielectric material. In accordance with at least one embodiment of the present disclosure, the performance of operation 404 can include forming a liner (for example, a liner substantially similar to the liner 140A described above with reference to FIG. 2) between the first electrically conductive contact and the first region of dielectric material. In accordance with at least one such embodiment, forming the liner includes forming the liner such that an uppermost surface of the liner is substantially coplanar with an uppermost surface of the first region of the fill material. In accordance with at least one embodiment of the present disclosure, forming the liner includes depositing a liner material, for example TiN, in the opening in the first region of dielectric material. In accordance with at least one embodiment of the present disclosure, the performance of operation 404 can include filling the liner with conductive metal, for example copper, to form the first electrically conductive contact embedded in the first region of dielectric material.

In accordance with at least one embodiment of the present disclosure, the performance of operation 404 can include recessing the first electrically conductive contact relative to the first region of dielectric material. In accordance with at least one embodiment of the present disclosure, recessing the first electrically conductive contact can include, for example, etching the metal of the first electrically conductive contact. In accordance with at least one embodiment of the present disclosure, recessing the first electrically conductive contact can include CMP. In such embodiments, the performance of CMP contributes to the formation of the depressions (for example, depressions substantially similar to the depressions 120A described above with reference to FIG. 2), each of which has a greater depth than the rest of the recess formed by recessing the first electrically conductive contact. In accordance with at least one embodiment of the present disclosure, the depressions are formed by galvanic corrosion of the copper of the first electrically conductive contact that occurs during CMP. In accordance with at least one embodiment of the present disclosure, the performance of operation 404 can include performing CMP prior to recessing the first electrically conductive contact to form a recess (for example, a recess substantially similar to the recess 116A described above with reference to FIG. 2) over the entirety of the uppermost surface of the first electrically conductive contact.

In accordance with at least one embodiment of the present disclosure, the performance of operation 404 can include forming a barrier layer (for example, a barrier layer substantially similar to the barrier layer 136A described above with reference to FIG. 2). In accordance with at least one embodiment of the present disclosure, forming the barrier layer can include depositing a barrier layer material, for example Ni, on top of the recess and depressions of the uppermost surface of the electrically conductive contact.

In accordance with at least one embodiment of the present disclosure, the performance of operation 408 can include filling the recess and depressions on the uppermost surface of the first electrically conductive contact with a fill material to form a first region of fill material (for example, a first region of fill material substantially similar to the first region of fill material 128A described above with reference to FIG. 2). The fill material includes an intermetallic alloy.

In accordance with at least one alternative embodiment of the present disclosure, the performance of operation 408 can include selectively growing the fill material on the uppermost surface of the first electrically conductive contact. For embodiments including a barrier layer, such embodiments can include selectively growing the fill material on the uppermost surface of the barrier layer that is on the uppermost surface of the first electrically conductive contact. In accordance with at least one alternative embodiment of the present disclosure, the performance of operation 408 can include selective growth of self-assembled monolayers of the fill material. In accordance with at least one alternative embodiment of the present disclosure, the performance of operation 408 can include depositing the fill material and anneal cycling. In accordance with at least one alternative embodiment of the present disclosure, the performance of operation 408 can include electroless deposition or electroless plating of the fill material.

In accordance with at least one embodiment of the present disclosure, the performance of operation 412 can include the performance of sub-operations that are substantially similar to those described above with reference to operation 404. Similarly, the performance of operation 416 can include the performance of sub-operations that are substantially similar to those described above with reference to operation 408. Notably, because the second electrically conductive contact embedded in the second region of dielectric material is flipped vertically to enable hybrid bonding between the first and second regions of fill material, the surfaces referred to as uppermost surfaces of the first electrically conductive contact, first region of dielectric material, the first region of fill material, and related components are referred to as lowermost surfaces of the second electrically conductive contact, second region of dielectric material, the second region of fill material, and related components.

In accordance with at least one embodiment of the present disclosure, the performance of method 400 can also include forming a cap (for example, a cap substantially similar to the cap 348A described above with reference to FIG. 3) on at least one of the uppermost surface of the first region of dielectric material and the lowermost surface of the second region of dielectric material. In accordance with at least one embodiment of the present disclosure, the cap can be made of, for example SiCN.

In accordance with embodiments of the present disclosure, the performance of operation 420 can include cold-bonding the first region of fill material to the second region of fill material. Such embodiments are made possible by the use of a fill material that includes a non-oxidizing, relatively soft metal, such as gold, and therefore is able to be cold-bonded. In particular, gold is more malleable than copper or other traditional contact materials and is able to form an alloy with copper that has low conductivity. Gold can cold-weld to itself in the hybrid bonding process described herein, thereby enabling its application for low temperature bonding that is more versatile across technologies. For example, cold-bonding may be more appropriate for bonding thermally sensitive components. In a particular example, cold-bonding can mitigate the risk of overwriting a thermally sensitive inference memory, like phase-change memory, by avoiding the use of heat during the bonding of the memory die to another die.

In addition to embodiments described above, other embodiments having fewer operational steps, more operational steps, or different operational steps are contemplated. Also, some embodiments may perform some or all of the above operational steps in a different order. Furthermore, multiple operations may occur at the same time or as an internal part of a larger process.

In the foregoing, reference is made to various embodiments. It should be understood, however, that this disclosure is not limited to the specifically described embodiments. Instead, any combination of the described features and elements, whether related to different embodiments or not, is contemplated to implement and practice this disclosure. Many modifications and variations may be apparent to those of ordinary skill in the art without departing from the scope and spirit of the described embodiments. Furthermore, although embodiments of this disclosure may achieve advantages over other possible solutions or over the prior art, whether or not a particular advantage is achieved by a given embodiment is not limiting of this disclosure. Thus, the described aspects, features, embodiments, and advantages are merely illustrative and are not considered elements or limitations of the appended claims except where explicitly recited in a claim(s).

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. However, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to the skilled in the art. Therefore, it is intended that the following claims be interpreted as covering all such alterations and modifications as fall within the true spirit and scope of the invention.

What is claimed is:

1. A semiconductor device, comprising:
an electrically conductive contact embedded in a region of dielectric material, the electrically conductive contact having an uppermost surface including a recess and a depression, the recess recessed a first depth relative to an uppermost surface of the region of dielectric material, and the depression recessed a second depth relative to the uppermost surface of the region of dielectric material, the second depth greater than the first depth; and
a region of fill material formed in the recess and the depression of the uppermost surface of the electrically conductive contact, the fill material including an intermetallic alloy.

2. The semiconductor device of claim 1, wherein:
the intermetallic alloy includes copper.

3. The semiconductor device of claim 1, wherein:
an uppermost surface of the region of the fill material is substantially coplanar with the uppermost surface of the region of dielectric material.

4. The semiconductor device of claim 1, further comprising:
a barrier layer arranged between the uppermost surface of the electrically conductive contact and the fill material such that the barrier layer is in direct contact with the uppermost surface of the electrically conductive contact.

5. The semiconductor device of claim 1, further comprising:
a cap formed on the uppermost surface of the region of dielectric material.

6. The semiconductor device of claim 5, wherein:
an uppermost surface of the region of the fill material is substantially coplanar with an uppermost surface of the cap.

7. The semiconductor device of claim 1, further comprising:
a liner separating the electrically conductive contact and the region of dielectric material.

8. The semiconductor device of claim 7, wherein:
an uppermost surface of the liner is substantially coplanar with an uppermost surface of the region of the fill material.

9. A semiconductor device, comprising:
a first electrically conductive contact embedded in a first region of dielectric material, the first electrically conductive contact having an uppermost surface including a recess and a depression, the recess recessed a first depth relative to an uppermost surface of the first region of dielectric material, and the depression recessed a second depth relative to the uppermost surface of the first region of dielectric material, the second depth greater than the first depth;
a second electrically conductive contact embedded in a second region of dielectric material, the second electrically conductive contact having a lowermost surface that is recessed relative to a lowermost surface of the second region of dielectric material;
a first region of fill material formed in the recess and the depression of the uppermost surface of the first electrically conductive contact; and
a second region of the fill material arranged on the lowermost surface of the second electrically conductive contact, wherein:
the fill material includes an intermetallic alloy, and
the first region of the fill material is in direct contact with the second region of the fill material.

10. The semiconductor device of claim 9, wherein:
an uppermost surface of the first region of the fill material is substantially coplanar with the uppermost surface of the first region of dielectric material.

11. The semiconductor device of claim 9, further comprising:
a barrier layer arranged between the uppermost surface of the first electrically conductive contact and the first region of the fill material such that the barrier layer is in direct contact with the uppermost surface of the first electrically conductive contact.

12. The semiconductor device of claim 9, further comprising:
a cap formed on the uppermost surface of the first region of dielectric material.

13. The semiconductor device of claim 12, wherein:
an uppermost surface of the first region of the fill material is substantially coplanar with an uppermost surface of the cap.

14. The semiconductor device of claim 9, further comprising:
a liner separating the first electrically conductive contact and the first region of dielectric material.

15. The semiconductor device of claim 14, wherein:
an uppermost surface of the liner is substantially coplanar with an uppermost surface of the first region of the fill material.

16. A method of forming a semiconductor device, the method comprising:
providing a first electrically conductive contact embedded in a first region of dielectric material, the first electrically conductive contact having an uppermost surface including a recess and a depression, the recess recessed a first depth relative to an uppermost surface of the first region of dielectric material, and the depression recessed a second depth relative to the uppermost surface of the region of dielectric material, the second depth greater than the first depth; and
forming a first region of fill material in the recess and the depression of the uppermost surface of the first electrically conductive contact, the fill material including an intermetallic alloy.

17. The method of claim 16, further comprising:
providing a second electrically conductive contact embedded in a second region of dielectric material, the second electrically conductive contact having a lowermost surface that is recessed relative to a lowermost surface of the second region of dielectric material;
forming a second region of the fill material on the lowermost surface of the second electrically conductive contact; and
bonding the first region of the fill material directly to the second region of the fill material.

18. The method of claim 17, further comprising:
bonding the first region of dielectric material to the second region of dielectric material.

19. The method of claim 17, further comprising:
forming a cap on at least one of the uppermost surface of the first region of dielectric material and the lowermost surface of the second region of dielectric material.

20. The method of claim 17, wherein:
bonding the first region of the fill material directly to the second region of the fill material includes cold bonding.
